(19) United States
(12) Patent Application Publication
(10) Pub. No.: US 2024/0260410 A1
(43) Pub. Date: Aug. 1, 2024

(54) ORGANIC LIGHT-EMITTING DIODE DISPLAY DEVICE AND METHOD OF MANUFACTURING THE SAME

(71) Applicant: LG Display Co., Ltd., Seoul (KR)

(72) Inventors: Ho-Jin KIM, Paju-si (KR); Ji-Yeon PARK, Paju-si (KR)

(21) Appl. No.: 18/514,950

(22) Filed: Nov. 20, 2023

(30) Foreign Application Priority Data
Jan. 30, 2023 (KR) 10-2023-0011626

(51) Int. Cl. H10K 59/80; H10K 59/12; H10K 59/35; H10K 59/38; H10K 59/70

(52) U.S. Cl. CPC H10K 59/8731; H10K 59/1201; H10K 59/351; H10K 59/38; H10K 59/70; H10K 2102/351

(57) ABSTRACT

An organic light-emitting diode display device can include a substrate including a first sub-pixel and a second sub-pixel; an interlayer insulation layer over the substrate and having different heights; and a first light-emitting diode disposed at the first sub-pixel and a second light-emitting diode disposed at the second sub-pixel over the substrate, wherein each of the first light-emitting diode or second light-emitting diode includes a first electrode, a light-emitting layer, and a second electrode, and the light-emitting layer includes a first stack, a charge generation layer, and a second stack, and wherein the second electrode of the first light-emitting diode is electrically connected to the charge generation layer of the first light-emitting diode, and the second electrode of the second light-emitting diode is separated from the charge generation layer of the second light-emitting diode.

### CROSS-REFERENCE TO RELATED APPLICATION

The present application claims priority to Korean Patent Application No. 10-2023-0011626 filed in the Republic of Korea on Jan. 30, 2023, the entire contents of which are hereby expressly incorporated by reference into the present application.

### BACKGROUND

### Technical Field

The present disclosure relates to a display device, and more particularly, to an organic light-emitting diode display device with improved color reproducibility and a method of manufacturing the same.

### Description of the Related Art

As the information society progresses, a demand for different types of display devices increases, and flat panel display devices (FPD) such as liquid crystal display devices (LCD) and organic light-emitting diode display devices (OLED) have been developed and applied to various fields.

Among the flat panel display devices, organic light-emitting diode display devices, which are also referred to as organic electroluminescent display devices, emit light due to the radiative recombination of an exciton. The exciton is formed from an electron and a hole by injecting charges into a light-emitting layer between a cathode for injecting electrons and an anode for injecting holes in a light-emitting diode.

The organic light-emitting diode display device can be formed over a flexible substrate, such as plastic, and offers various advantages and improved properties. For instance, because it is self-luminous, the organic light-emitting diode display device has an excellent contrast ratio and an ultra-thin thickness, and has a response time of several micro seconds. As such, there are advantages in displaying moving images and videos without delays using the organic light-emitting diode display device.

Additionally, the organic light-emitting diode display device has a wide viewing angle and is stable under low temperatures. Further, since the organic light-emitting diode display device is generally driven by a low voltage of direct current (DC) (e.g., 5V to 15V), it is easy to design and manufacture the driving circuits of the organic light-emitting diode display device.

Recently, as the organic light-emitting diode display device is applied to various fields, a display device having high resolution is required. In order to implement such a high resolution, more sub-pixels are provided within the same area. Accordingly, the area of each sub-pixel is reduced, and a distance between adjacent sub-pixels is also decreased.

### BRIEF SUMMARY

Inventors recognized that the decrease in the distance between adjacent sub-pixels may cause a lateral leakage current between adjacent sub-pixels. The lateral leakage current may cause unwanted sub-pixels to emit light, which lowers the color reproducibility of display devices.

The present disclosure provides an organic light-emitting diode display device and a method of manufacturing the same that substantially obviate one or more of the limitations and disadvantages described above and associated with the background art.

For example, the present disclosure provides an organic light-emitting diode display device capable of minimizing a lateral leakage current between adjacent sub-pixels and a method of manufacturing the same.

The present disclosure provides an organic light-emitting diode display device capable of improving color purity at a low gray level and a method of manufacturing the same.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

To achieve these and other aspects of the present disclosure, as embodied and broadly described herein, an organic light-emitting diode display device includes a substrate including a first sub-pixel and a second sub-pixel; an interlayer insulation layer over the substrate and having different heights; and a first light-emitting diode disposed at the first sub-pixel and a second light-emitting diode disposed at the second sub-pixel over the substrate, wherein each of the first light-emitting diode or second light-emitting diode includes a first electrode, a light-emitting layer, and a second electrode, and the light-emitting layer includes a first stack, a charge generation layer, and a second stack, and wherein the second electrode of the first light-emitting diode is electrically connected to the charge generation layer of the first light-emitting diode, and the second electrode of the second light-emitting diode is separated from the charge generation layer of the second light-emitting diode.

In another aspect, an organic light-emitting diode display device includes a substrate including a first sub-pixel and a second sub-pixel; an interlayer insulation layer over the substrate; and a light-emitting diode disposed at each of the first and second sub-pixels over the substrate, wherein the light-emitting diode includes a first electrode, a light-emitting layer, and a second electrode, and the light-emitting layer includes a first stack, a charge generation layer, and a second stack, and wherein a first height of the interlayer insulation layer in the first sub-pixel is higher than a second height of the interlayer insulation layer in the second sub-pixel.

In another aspect, a method of manufacturing an organic light-emitting diode display device includes forming an interlayer insulation layer over a substrate including a first sub-pixel and a second sub-pixel, the interlayer insulation layer having different heights between a first portion of the interlayer insulation layer on the first sub-pixel and a second portion of the interlayer insulation layer on the second sub-pixel; forming a first electrode at each of the first and second sub-pixels over the interlayer insulation layer; forming a light-emitting layer including a first stack, a charge generation layer, and a second stack over each first electrode; and forming a second electrode over each light-emitting layer, wherein the second electrode in the first sub-pixel is electrically short-circuited to the charge generation layer in the first sub-pixel, and the second electrode in the second sub-pixel is separated from the charge generation layer in the second sub-pixel.

In another aspect, An organic light-emitting diode display device includes a substrate including a first sub-pixel and a second sub-pixel; an interlayer insulation layer over the substrate and having a first height at the first sub-pixel and a second height at the second sub-pixel; and a first light-emitting diode disposed at the first sub-pixel and a second light-emitting diode disposed at the second sub-pixel over the substrate, each of the first light-emitting diode or second light-emitting diode including a first electrode, a light-emitting layer, and a second electrode; wherein a difference between the first height and the second height is greater than a thickness of the light-emitting layer.

It is to be understood that both the foregoing general description and the following detailed description are examples and are intended to provide further explanation of the inventive concepts as claimed.

### BRIEF DESCRIPTION OF THE SEVERAL VIEWS OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a plan view schematically illustrating an organic light-emitting diode display device according to a first embodiment of the present disclosure;

FIG. 2 is a cross-sectional view of an organic light-emitting diode display device according to the first embodiment of the present disclosure;

FIG. 3 is a graph showing a spectrum of light emitted from the blue sub-pixel of the organic light-emitting diode display device according to the first embodiment of the present disclosure at low gray levels;

FIG. 4 is a graph showing a spectrum of light emitted from a blue sub-pixel of an organic light-emitting diode display device according to a comparative example at low gray levels;

FIGS. 5A to 5I are schematic cross-sectional views of an organic light-emitting diode display device in steps of manufacturing the organic light-emitting diode display device according to the first embodiment of the present disclosure;

FIGS. 6A to 6E are schematic cross-sectional views of an organic light-emitting diode display device in steps of manufacturing the organic light-emitting diode display device of another example according to the first embodiment of the present disclosure;

FIG. 7 is a plan view schematically illustrating an organic light-emitting diode display device according to a second embodiment of the present disclosure; and

FIG. 8 is a cross-sectional view of an organic light-emitting diode display device according to the second embodiment of the present disclosure.

### DETAILED DESCRIPTION

Reference will now be made in detail to embodiments, examples of which are illustrated in the accompanying drawings. The same or like reference numbers may be used throughout the drawings to refer to the same or like parts.

Hereinafter, an organic light-emitting diode display device and a method of manufacturing the same according to embodiments of the present disclosure will be described in detail with reference to the accompanying drawings.

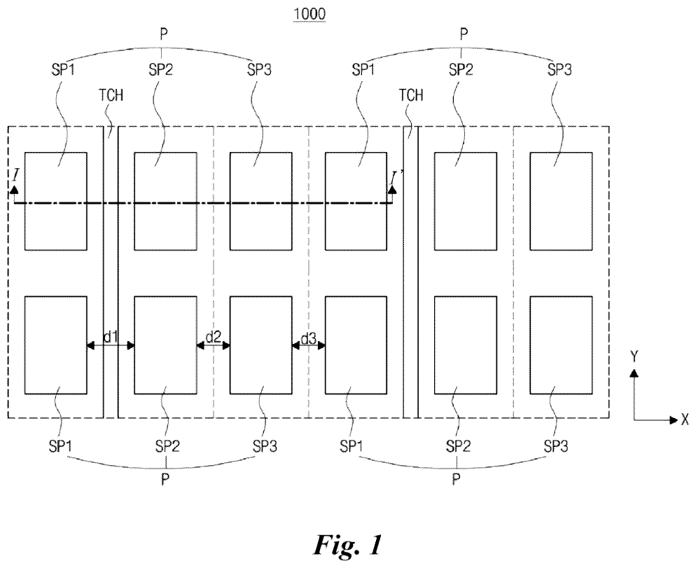

FIG. 1 is a plan view schematically illustrating an organic light-emitting diode display device according to a first embodiment of the present disclosure.

In FIG. 1, the organic light-emitting diode display device 1000 according to the first embodiment of the present disclosure can include a plurality of pixels P arranged in a matrix form along a first direction, which is an X direction, and a second direction, which is a Y direction. Each pixel P can include a plurality of sub-pixels SP1, SP2, and SP3. Four pixels P, which include two pixels arranged along the first direction and two pixels arranged along second direction, are shown in FIG. 1.

One pixel P can include three sub-pixels SP1, SP2, and SP3. That is, one pixel P can include first, second, and third sub-pixels SP1, SP2, and SP3. However, the embodiments of the present disclosure are not limited thereto. The number of sub-pixels included in one pixel P can vary.

For example, the first, second, and third sub-pixels SP1, SP2, and SP3 can be red, green, and blue sub-pixels, respectively. Hereinafter, the first, second, and third sub-pixels SP1, SP2, and SP3 can be referred to as the red, green, and blue sub-pixels SP1, SP2, and SP3.

Here, the terms of first, second, and third can be referred to according to the order of arrangement for convenience, and the terms of first, second, and third are not limited to the red, green, and blue colors, respectively. That is, the blue sub-pixel SP3 can be a first sub-pixel, one of the red sub-pixel SP1 and the green sub-pixel SP2 can be a second sub-pixel, and the other can be a third sub-pixel.

At least one thin film transistor and a light-emitting diode can be provided at each of the red, green, and blue sub-pixels SP1, SP2, and SP3. In FIG. 1, an area corresponding to each sub-pixel SP1, SP2, and SP3 can substantially mean an emission area.

A trench TCH can be provided between the red and green sub-pixels SP1 and SP2 adjacent to each other along the first direction. The trench TCH can be extended along the second direction.

In some embodiments, the trench TCH may not be provided between the blue sub-pixel SP3 and another sub-pixel adjacent thereto along the first direction. That is, the trench TCH may not be provided between the green and blue sub-pixels SP2 and SP3 and between the blue and red sub-pixels SP3 and SP1 adjacent to each other along the first direction.

A first distance d1 between the emission areas of the red and green sub-pixels SP1 and SP2 with the trench TCH provided therebetween can be greater than a second distance d2 between the emission areas of the green and blue sub-pixels SP2 and SP3 without the trench TCH provided therebetween and a third distance d3 between the emission areas of the blue and red sub-pixels SP3 and SP1 without the trench TCH provided therebetween. Here, the second distance d2 and the third distance d3 can be equal to each other.

Meanwhile, the trench TCH may not be provided between two sub-pixels adjacent to each other along the second direction, that is, between two red sub-pixels SP1, between two green sub-pixels SP2, and between two blue sub-pixels SP3. However, the embodiments of the present disclosure are not limited thereto. Alternatively or additionally, the trench TCH can be provided between two sub-pixels SP1, SP2, and SP3 adjacent to each other along the second direction.

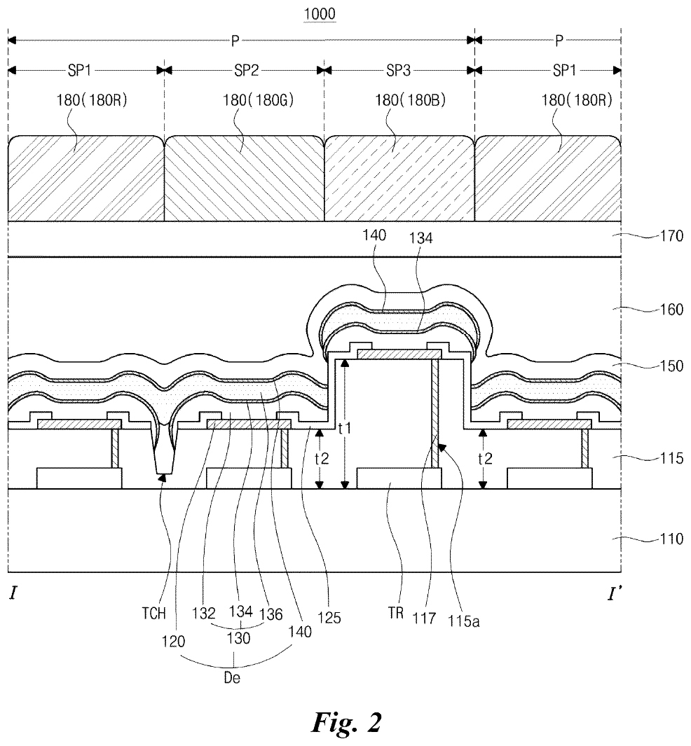

A cross-sectional structure of the organic light-emitting diode display device according to the first embodiment of the present disclosure will be described with reference to FIG. 2.

FIG. 2 is a cross-sectional view of an organic light-emitting diode display device according to the first embodiment of the present disclosure and shows a cross-section taken along the line I-I′ of FIG. 1. Here, the organic light-emitting diode display device 1000 will be described as an example of a top emission type.

In FIG. 2, the organic light-emitting diode display device 1000 of the first embodiment of the present disclosure can include a plurality of sub-pixels, for example, red, green, and blue sub-pixels SP1, SP2, and SP3. Each of the red, green, and blue sub-pixels SP1, SP2, and SP3 can include a transistor TR and a light-emitting diode De.

For example, the transistor TR can be disposed in each of the red, green, and blue sub-pixels SP1, SP2, and SP3 over a substrate 110. The red, green, and blue sub-pixels SP1, SP2, and SP3 can constitute one pixel P.

Here, the substrate 110 can be formed of a semiconductor material. For example, the substrate 110 can be a wafer formed of single crystal silicon. However, embodiments of the present disclosure are not limited thereto. Alternatively or additionally, the substrate 110 can be formed of an insulating material such as glass or plastic.

The transistor TR can be a metal oxide semiconductor field effect transistor (MOSFET). However, the embodiments of the present disclosure are not limited thereto. Alternatively or additionally, the transistor TR can be a thin film transistor (TFT).

The transistor TR can be a driving transistor connected to the light-emitting diode De. In addition, at least one transistor, at least one signal line, and at least one electrode, which can be connected to the driving transistor, can be further provided over the substrate 110.

For example, a switching transistor, a sensing transistor, a storage capacitor, a gate line, a data line, a power line, a sensing line and/or a reference line can be further provided over the substrate 110.

The switching transistor can be connected to the gate line, the data line, and the driving transistor and can be switched according to a gate signal of the gate line to thereby transmit a data signal of the data line to the driving transistor.

The driving transistor can be connected to the switching transistor, the power line, and the light-emitting diode De and can be switched according to the data signal transmitted from the switching transistor to thereby transmit a current according to a high potential voltage of the power line to the light-emitting diode De.

The sensing transistor can be connected to the driving transistor, the sensing line, and the reference line and can be switched according to a sensing signal of the sensing line to thereby transmit a reference voltage of the reference line to the driving transistor or detect a voltage of the driving transistor.

The storage capacitor can be connected to the switching transistor and the driving transistor and can serve to maintain the data signal transmitted from the switching transistor for one frame.

Next, an interlayer insulation layer 115 can be provided over the transistor TR. The interlayer insulation layer 115 can be disposed over a substantially entire surface of the substrate 110. The interlayer insulation layer 115 can have a via hole 115a exposing the transistor TR of each sub-pixel SP1, SP2, and SP3.

Here, the interlayer insulation layer 115 in the red and green sub-pixels SP1 and SP2 can have the same thickness and height. The thickness and height of the interlayer insulation layer 115 in the blue sub-pixel SP3 can be different from the thickness and height of the interlayer insulation layer 115 in the red and green sub-pixels SP1 and SP2. That is, the thickness and height of the interlayer insulation layer 115 in the blue sub-pixel SP3 can be greater than the thickness and height of the interlayer insulation layer 115 in the red and green sub-pixels SP1 and SP2.

Accordingly, a depth of the via hole 115a in the blue sub-pixel SP3 can be deeper than a depth of the via hole 115a in each of the red and green sub-pixels SP1 and SP2.

For example, a portion of the interlayer insulation layer 115 in the blue sub-pixel SP3 can have a first thickness t1, and portions of the interlayer insulation layer 115 in the red and green sub-pixels SP1 and SP2 can have a second thickness t2. The first thickness t1 can be greater than the second thickness t2. Accordingly, a first height of the portion of the interlayer insulation layer 115 in the blue sub-pixel SP3 can be higher than a second height of the portions of the interlayer insulation layer 115 in the red and green sub-pixels SP1 and SP2.

In this case, a side surface of the portion of the interlayer insulation layer 115 in the blue sub-pixel SP3 can be substantially perpendicular to the substrate 110 or can be reversely inclined with respect to the substrate 110 such that a width of the portion of the interlayer insulation layer 115 corresponding to the blue sub-pixel SP3 may increase upwards, that is, far away from the substrate 110.

The interlayer insulation layer 115 can be formed as a single layer or multiple layers. For example, the interlayer insulation layer 115 can be formed of an inorganic insulating material such as silicon oxide (SiOx) or silicon nitride (SiNx). However, embodiments of the present disclosure are not limited thereto. Alternatively or additionally, the interlayer insulation layer 115 can be formed of an organic insulating material such as an acrylic resin, epoxy resin, phenol resin, polyamide resin, or polyimide resin.

A first electrode 120 can be provided in each of the red, green, and blue sub-pixels SP1, SP2, and SP3 over the interlayer insulation layer 115. The first electrode 120 can be connected to the transistor TR through the via hole 115a provided in the interlayer insulation layer 115. In this case, the first electrode 120 can be electrically connected to a source or drain electrode of the transistor TR.

Here, a via electrode 117 made of a metal material can be provided in the via hole 115a. For example, the via electrode 117 can be formed of tungsten (W). However, the embodiments of the present disclosure are not limited thereto.

Alternatively or additionally, the via electrode 117 can be omitted, and the first electrode 120 can be provided in the via hole 115a to be directly connected to the transistor TR.

The first electrode 120 can include a conductive material having relatively high work function.

For example, as mentioned above, when the organic light-emitting diode display device 1000 according to the first embodiment of the present disclosure is a top emission type, the first electrode 120 can be formed as a structure having relatively high reflectance such as a triple-layer structure of titanium, aluminum, and titanium (Ti/Al/Ti), a triple-layer structure of indium tin oxide, aluminum, and indium tin oxide (ITO/Al/ITO), a triple-layer structure of indium tin oxide, silver, and indium tin oxide (ITO/Ag/ITO), or a triple-layer structure of indium tin oxide, silver alloy, and indium tin oxide (ITO/Ag alloy/ITO). Here, the silver alloy can be an alloy of silver-palladium-copper (APC).

Alternatively or additionally, the first electrode 120 can include a transparent electrode layer formed of a transparent conductive oxide (TCO) such as indium tin oxide (ITO) or indium zinc oxide (IZO), and a reflective layer can be disposed under the transparent electrode layer. The reflective layer can be electrically connected to the transparent electrode layer.

A bank 125 can be disposed over the first electrode 120. The bank 125 can cover edges of the first electrode 120 and have an opening exposing a central portion of the first electrode 120. A portion corresponding to the opening of the bank 125, that is, the portion of the first electrode 120 exposed by the bank 125 can be defined as an emission area. A portion except for the emission area can be defined as a non-emission area.

For example, the bank 125 can be formed of an inorganic insulating material such as silicon oxide (SiOx) or silicon nitride (SiNx). However, the embodiments of the present disclosure are not limited thereto. Alternatively or additionally, the bank 125 can be formed of an organic insulating material such as an acrylic resin, epoxy resin, phenol resin, polyamide resin, or polyimide resin.

The bank 125 can be formed as a single layer or multiple layers.

Meanwhile, a trench TCH can be formed in the bank 125 and the interlayer insulation layer 115 between adjacent sub-pixels where the thickness and the height of the interlayer insulation layer 115 are the same, that is, at a boundary of the red and green sub-pixels SP1 and SP2. On the other hand, the trench TCH may not be formed between adjacent sub-pixels where the thickness and the height of the interlayer insulation layer 115 are different from each other, that is, at a boundary of the green and blue sub-pixels SP2 and SP3 and at a boundary of the blue and red sub-pixels SP3 and SP1. Accordingly, the bank 125 can be formed to have a step difference along the side surface of the interlayer insulation layer 115 having the first thickness t1 between the green and blue sub-pixels SP2 and SP3 and between the blue and red sub-pixels SP3 and SP1.

Due to the trench TCH, a distance between the first electrodes 120 of the red and green sub-pixels SP1 and SP2 can be greater than a distance between the electrodes 120 of the green and blue sub-pixels SP2 and SP3 and a distance between the electrodes 120 of the blue and red sub-pixels SP3 and SP1.

In the first embodiment of the present disclosure, the trench TCH can be formed in both the interlayer insulation layer 115 and the bank 125 as an example, but the trench TCH can be formed only in the interlayer insulation layer 115. Namely, in other embodiments, the bank 125 between the adjacent red and green sub-pixels SP1 and SP2 may not be disconnected and be continuously connected to cover the trench TCH.

The trench TCH can separate a light-emitting layer 130 of the adjacent red and green sub-pixels SP1 and SP2 in a subsequent process from each other to thereby minimize a lateral leakage current.

For example, when the trench TCH is not formed, first and second stacks 132 and 136 and a charge generation layer 134 can be connected to each other between the adjacent red and green sub-pixels SP1 and SP2, so that a lateral leakage current can be generated. The lateral leakage current may cause undesired red or green sub-pixels SP1 or SP2 to emit light and decrease the color reproducibility.

The decrease in the color reproducibility may be greater when the lateral leakage current occurs between the sub-pixels emitting light of different colors than when the lateral leakage current occurs between the sub-pixels emitting light of the same color.

Accordingly, in the organic light-emitting diode display device 1000 according to the first embodiment of the present disclosure, to minimize the lateral leakage current between the red and green sub-pixels SP1 and SP2 emitting light of different colors, the trench TCH can be disposed between the red and green sub-pixels SP1 and SP2 emitting light of different colors. Here, the first stack 132 and the charge generation layer 134 between the adjacent red and green sub-pixels SP1 and SP2 can be separated by the trench TCH, while the second stack 136 between the adjacent red and green sub-pixels SP1 and SP2 can be connected to each other without being separated.

Alternatively or additionally, the first stack 132, the charge generation layer 134, and the second stack 134 between the adjacent red and green sub-pixels SP1 and SP2 can all be separated from each other by the trench TCH.

In addition, due to the difference in thickness and height of the interlayer insulation layer 115, the light-emitting layer 130 of the blue sub-pixel SP3 can be separated from the light-emitting layer 130 of the green and red sub-pixels SP2 and SP1 adjacent thereto, thereby minimizing the lateral leakage current. This will be described in detail later.

Meanwhile, the trench TCH may not be provided between the red sub-pixels SP1, between the green sub-pixels SP2, and between the blue sub-pixels SP3 emitting light of the same color.

For example, when the organic light-emitting diode display device 1000 according to the first embodiment of the present disclosure is a stripe type, as shown in FIG. 1, the red, green, and blue sub-pixels SP1, SP2, and SP3 of different colors can be sequentially repeatedly arranged along the first direction, and the red sub-pixels SP1, green sub-pixels SP2, and blue sub-pixels SP3 of the same color can be arranged along the second direction. In this case, the trench TCH can be provided to have a line shape in the second direction between the red and green sub-pixels SP1 and SP2 emitting light of different colors adjacent to each other along the first direction of FIG. 1 and may not be provided between the sub-pixels SP1, SP2, and SP3 emitting light of the same color adjacent to each other along the second direction of FIG. 1.

Next, the light-emitting layer 130 can be disposed over the first electrode 120 exposed through the opening of the bank 125 and the bank 125. The light-emitting layer 130 can include the first stack 132, the charge generation layer 134, and the second stack 136.

The first stack 132 can include at least one hole injecting layer (HIL), at least one hole transporting layer (HTL), at least one emitting material layer (EML), and at least one electron transporting layer (ETL). The emitting material layer (EML) of the first stack 132 can emit one of red light, green light, blue light, and yellow light.

The charge generation layer (CGL) 134 can include a negative type charge generation layer (N-type CGL) for providing an electron to the first stack 132 and a positive type charge generation layer (P-type CGL) for providing a hole to the second stack 136.

The second stack 136 can include at least one hole transporting layer (HTL), at least one emitting material layer (EML), at least one electron transporting layer (ETL), and at least one electron injecting layer (EIL). The emitting material layer (EML) of the second stack 136 can emit one of red light, green light, blue light, and yellow light.

Here, the emitting material layer (EML) of the second stack 136 can emit light of a different color from the emitting material layer (EML) of the first stack 132. For example, the emitting material layer (EML) of the first stack 132 can emit blue light, and the emitting material layer (EML) of the second stack 136 can emit red light and green light. Alternatively or additionally, the emitting material layer (EML) of the first stack 132 can emit blue light, and the emitting material layer (EML) of the second stack 136 can emit yellow light.

As described above, at least one including the charge generation layer 134 of the first stack 132, the charge generation layer 134, and the second stack 136 of the light-emitting layer 130 can be disconnected over the trench TCH due to a step difference of the trench TCH and be spaced apart for each of the red and green sub-pixels SP1 and SP2 without contacting each other.

For example, the first stack 132 and the charge generation layer 134 can be spaced apart for each of the red and green sub-pixels SP1 and SP2. In this case, the first stack 132 and the charge generation layer 134 can be thinner as it approaches the substrate 110 and then be cut off over the trench TCH. Meanwhile, the same materials as the first stack 132 and the charge generation layer 134 can be stacked in the trench TCH.

In addition, due to the difference in the thickness and height of the interlayer insulation layer 115, the light-emitting layer 130 of the blue sub-pixel SP3 can be separated from the light-emitting layer 130 of each of the red sub-pixel SP1 and the green sub-pixel SP2 adjacent thereto. That is, a portion of the light-emitting layer 130 of the blue sub-pixel SP3, which is disposed over the interlayer insulation layer 115 having the first thickness t1 and the first height, can be separated from portions of the light-emitting layer 130 of the red and green sub-pixels SP1 and SP2, which are disposed over the interlayer insulation layer 115 having the second thickness t2 and the second height.

In this case, a difference between the first thickness t1 and the second thickness t2, beneficially, can be greater than a thickness of the light-emitting layer 130. The thickness of the light-emitting layer 130 can be defined as a distance between the first electrode 120 and a second electrode 140. Accordingly, the first stack 132, the charge generation layer 134, and the second stack 136 of the blue sub-pixel SP3 can be separated from the first stack 132, the charge generation layer 134, and the second stack 136 of each of the red and green sub-pixel SP1 and SP2 adjacent thereto. For example, the difference between the first thickness t1 and the second thickness t2 can be 3000 Å or more. However, the embodiments of the disclosure are not limited thereto.

Each of the first stack 132, the charge generation layer 134, and the second stack 136 of the blue sub-pixel SP3 can be formed along the bank 125 formed at the side surface of the interlayer insulation layer 115 having the first thickness t1, and can be thinner as it approaches the substrate 110 and then be cut off over the trench TCH. In this case, the first stack 132 and the charge generation layer 134 can be in contact with the bank 125, and the second stack 136 can be spaced apart from the bank 125 and expose opposite edges of the charge generation layer 134. On the other hand, the first stack 132, the charge generation layer 134, and the second stack 136 of each of the red and green sub-pixels SP1 and SP2 can be in contact with the bank 125 formed at the side surface of the interlayer insulation layer 115 having the first thickness t1.

In the organic light-emitting diode display device 1000 according to the first embodiment of the present disclosure, the first stack 132 and the charge generation layer 134 can be separated and spaced apart for each of the red and green sub-pixels SP1 and SP2 over the trench TCH, and the first stack 132, the charge generation layer 134, and the second stack 136 of the blue sub-pixel SP3 can be separated from the first stack 132, the charge generation layer 134, and the second stack 136 of the red and green sub-pixel SP1 and SP2 adjacent thereto due to the difference in the thickness and height of the interlayer insulation layer 115, thereby minimizing the lateral leakage current between the red, green, and blue sub-pixels SP1, SP2, and SP3 emitting light of different colors.

Meanwhile, in the first embodiment of the present disclosure, the light-emitting layer 130 can have a two-stack structure including the first stack 132, the charge generation layer 134, and the second stack 136 as an example, but in other embodiments, the light-emitting layer 130 can have a multi-stack structure including three or more stacks and two or more charge generation layers. In this case, two or more stacks and two or more charge generation layers can be separated by the trench TCH and the difference in the thickness and height of the interlayer insulation layer 115.

The second electrode 140 can be provided over the light-emitting layer 130. The second electrode 140 can be disposed over a substantially entire surface of the substrate 110.

The first electrode 120, the light-emitting layer 130, and the second electrode 140 can constitute the light-emitting diode De. Here, the first electrode 120 can serve as an anode, and the second electrode 140 can serve as a cathode. However, embodiments of the present disclosure are not limited thereto. Alternatively or additionally, the first electrode 120 can serve as a cathode, and the second electrode 140 can serve as an anode.

The second electrode 140 may not be separated over the trench TCH and can be connected to each other between the red and green sub-pixels SP1 and SP2. Alternatively or additionally, the second electrode 140 can be separated over the trench TCH and spaced apart for each of the red and green sub-pixels SP1 and SP2.

Meanwhile, the second electrode 140 of the blue sub-pixel SP3 can be separated from the second electrode 140 of the red and green sub-pixels SP1 and SP2 adjacent thereto. Opposite edges of the second electrode 140 of the blue sub-pixel SP3 can be thinner corresponding to the side surfaces of the interlayer insulation layer 115 having the first thickness t1 as it approaches the substrate 110 and then be cut off, thereby being in contact with the exposed charge generation layer 134 of the blue sub-pixel SP3. Accordingly, in the blue sub-pixel SP3, the second electrode 140 can be electrically connected to the charge generation layer 134. That is, in the blue sub-pixel SP3, the second electrode 140 can be electrically short-circuited to the charge generation layer 134 with relatively high resistance. The second electrode 140 of the blue sub-pixel SP3 can be spaced apart from the bank 125 formed at the side surface of the interlayer insulation layer 115 having the first thickness t1.

Ibn some embodiments, the second electrode 140 of each of the red and green sub-pixels SP1 and SP2 can be in contact with the bank 125 formed at the side surface of the interlayer insulation layer 115 having the first thickness t1.

Here, it has bed described that the second electrode 140 of the blue sub-pixel SP3 can be separated from the second electrode 140 of each of the red and green sub-pixels SP1 and SP2 adjacent thereto, but the embodiments of the present disclosure are not limited thereto. Alternatively or additionally, the second electrode 140 of the blue sub-pixel SP3 can be connected to the second electrode 140 of each of the red and green sub-pixels SP1 and SP2.

The second electrode 140 can be formed of a transparent conductive material, a semi-transmissive material, or a metal material having reflectance. The second electrode 140 can include a conductive material having relatively low work function.

For example, as stated above, when the organic light-emitting diode display device 1000 according to the first embodiment of the present disclosure is a top emission type, the second electrode 140 can be formed of a transparent conductive oxide (TCO) such as indium tin oxide (ITO) or indium zinc oxide (IZO) or a semi-transmissive metal material such as magnesium (Mg), silver (Ag), or an alloy of magnesium and silver (MgAg) capable of transmitting light.

First, second, and third encapsulation layers 150, 160, and 170 can be sequentially provided over the second electrode 140. The first and third encapsulation layers 150 and 170 can be formed of an inorganic insulating material, and the second encapsulation layer 160 can be formed of an organic insulating material.

For example, the first encapsulation layer 150 can be formed of an inorganic insulating material such as aluminum oxide (AlOx), silicon oxide (SiOx), or silicon nitride (SiNx), the third encapsulation layer 170 can be formed of an inorganic insulating material such as silicon oxide (SiOx) or silicon nitride (SiNx), and the second encapsulation layer 160 can be formed of an organic insulating material such as acrylic resin or epoxy resin.

The first, second, and third encapsulation layers 150, 160, and 170 can block external moisture and oxygen.

Next, a color filter 180 can be provided over the third encapsulation layer 170. The color filter 180 can include red, green, and blue color filters 180R, 180G, and 180B corresponding to the red, green, and blue sub-pixels SP1, SP2, and SP3, respectively.

Although not shown in the figures, a cover substrate or cover film can be provided over the color filter 180.

As described above, in the organic light-emitting diode display device 1000 according to the first embodiment of the present disclosure, by disposing the trench TCH between the adjacent red and green sub-pixels SP1 and SP2 and by making the thickness and height of the interlayer insulation layer 115 in the blue sub-pixel greater than the thickness and height of the interlayer insulation layer 115 in the red and green sub-pixels SP1 and SP2, the first stack 132 and the charge generation layer 134 between the adjacent sub-pixels SP1, SP2, and SP3 of different colors can be separated, thereby minimizing the lateral leakage current.

In some embodiments, in the blue sub-pixel SP3, the edges of the second electrode 140 can be in contact with the charge generation layer 134, the second electrode 140 and the charge generation layer 134 can be electrically connected to each other, thereby improving the color purity of blue light at the low gray levels.

For example, when the first stack 132 emits blue light and the second stack 136 emits red light and green light, the turn-on voltage for emitting the blue light may be relatively high, so that intensities of the red light and the green light can be relatively high at low gray levels where a relatively low voltage is applied, and the blue light can be greatly influenced by the red light and the green light. Accordingly, even if the color filter 180 is used, the blue sub-pixel SP3 cannot completely block light other than blue light, and thus the color purity of blue light can be low. Therefore, in the present disclosure, the second electrode 140 and the charge generation layer 134 of the blue sub-pixel SP3 can be short-circuited with relatively high resistance, thereby minimizing the intensities of the red light and the green light at the low gray levels and improving the purity of the blue light.

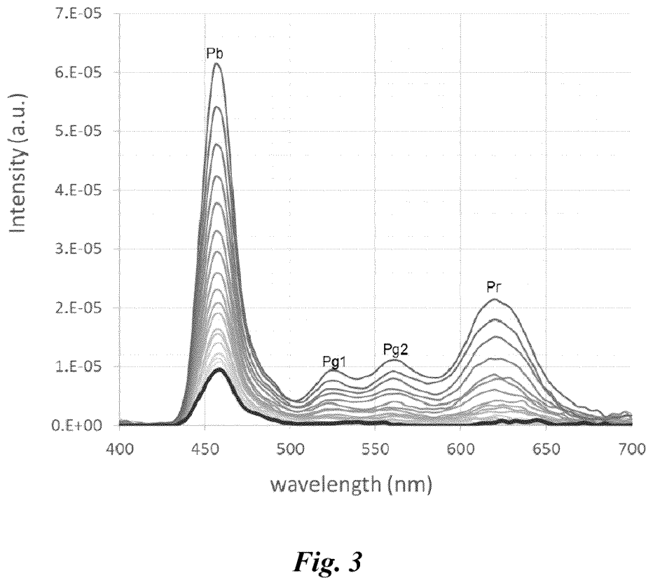

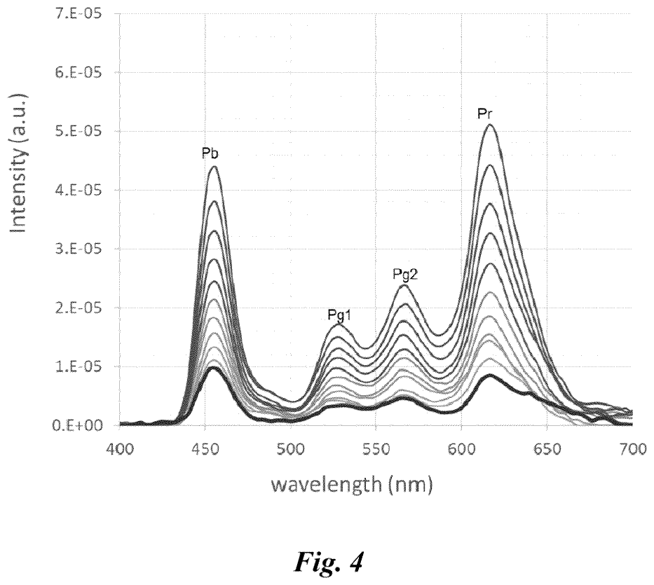

The improvement in the color purity of the blue light at the low gray levels of the organic light-emitting diode display device according to the first embodiment of the present disclosure will be described with reference to FIGS. 3 and 4.

FIG. 3 is a graph showing a spectrum of light emitted from the blue sub-pixel of the organic light-emitting diode display device according to the first embodiment of the present disclosure at low gray levels, and FIG. 4 is a graph showing a spectrum of light emitted from a blue sub-pixel of an organic light-emitting diode display device according to a comparative example at low gray levels. Here, FIGS. 3 and 4 show the spectrum from a gray level of the turn-on voltage to a 20 gray level, and the dark graph at the bottom represents the spectrum at the gray level of the turn-on voltage.

In the organic light-emitting diode display device according to the first embodiment of the present disclosure, the second electrode and the charge generation layer of the blue sub-pixel can be short-circuited with relatively high resistance, whereas in the organic light-emitting diode display device according to the comparative example, a second electrode and a charge generation layer of a blue sub-pixel may not be short-circuited and may be separated.

As shown in FIG. 3, when the turn-on voltage is applied, the light emitted from the light-emitting diode of the blue sub-pixel of the organic light-emitting diode display device according to the first embodiment of the present disclosure can have the blue peak Pb, but may not substantially have the green peaks Pg1 and Pg2 and the red peak Pr. In the light emitted from the light-emitting diode of the blue sub-pixel, the intensities of the blue peak Pb, the green peaks Pg1 and Pg2, and the red peak Pr can increase as the gray level increases, and the intensities of the green peaks Pg1 and Pg2 and the red peak Pr may be very small compared to the intensity of the blue peak Pb. The green peaks Pg1 and Pg2 and the red peak Pr may be blocked by the blue color filter. Accordingly in the organic light-emitting diode display device according to the first embodiment of the present disclosure, the purity of the blue light at the low gray levels can be improved.

In contrast, as shown in FIG. 4, when the turn-on voltage is applied, the light emitted from the light-emitting diode of the blue sub-pixel of the organic light-emitting diode display device according to the comparative example may have not only the blue peak Pb but also the green peaks Pg1 and Pg2 and the red peak Pr. In the light emitted from the light-emitting diode of the blue sub-pixel, the intensities of the blue peak Pb, the green peaks Pg1 and Pg2, and the red peak Pr can increase as the gray level increases, and the intensities of the green peaks Pg1 and Pg2 and the red peak Pr may be similar to or greater than the intensity of the blue peak Pb. Some of the green peaks Pg1 and Pg2 and the red peak Pr may not be completely blocked by the blue color filter and be output to the outside. Accordingly, in the organic light-emitting diode display device according to the comparative example, the purity of the blue light at the low gray levels may be lowered. This may cause a relatively large color shift, thereby decreasing the color reproducibility.

The color shift is the amount of change in color coordinates at a low gray level compared to the color coordinates at the maximum gray level, and the color shift of the blue color is preferably 0.02 or less. In the comparative example, the color shift of about 0.026 to 0.031 may occur, whereas in the first embodiment of the present disclosure, the color shift of about 0.007 can occur, so that the color reproducibility can be improved by increasing the color purity.

As such, in the organic light-emitting diode display device 1000 according to the first embodiment of the present disclosure, by disposing the trench TCH or varying the thickness and height of the interlayer insulation layer 115 between the adjacent sub-pixels SP1, SP2, and SP3 of different colors, the first stack 132 and the charge generation layer 134 between the adjacent sub-pixels SP1, SP2, and SP3 of different colors can be separated, so that the lateral leakage current can be minimized.

At this time, since the trench TCH can be omitted due to the difference in the thickness and height of the interlayer insulation layer 115, the size of the emission area can be increased within the same area, thereby increasing the aperture ratio.

In some embodiments, in the blue sub-pixel SP3, the edges of the second electrode 140 can be in contact with the charge generation layer 134 to electrically connect the second electrode 140 and the charge generation layer 134, which improves the color purity of the blue light at the low gray levels.

Furthermore, since the intensities of the red light and the green light at the low gray levels are relatively small, the color material of the blue color filter 180B can be reduced or the thickness of the blue color filter 180B can be decreased. Accordingly, the transmittance of the blue color filter 180B can be increased, so that the efficiency of the blue color can be increased.

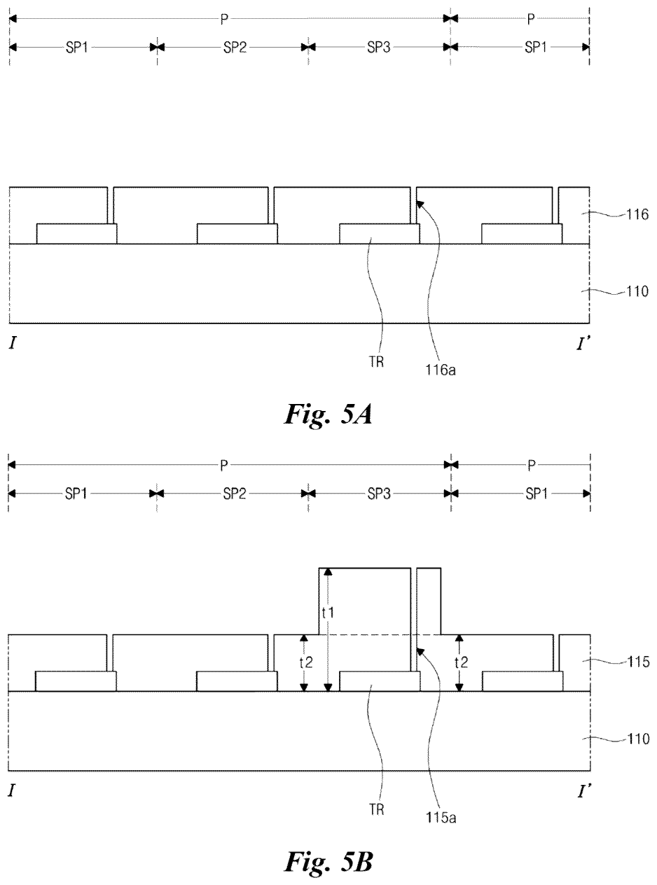

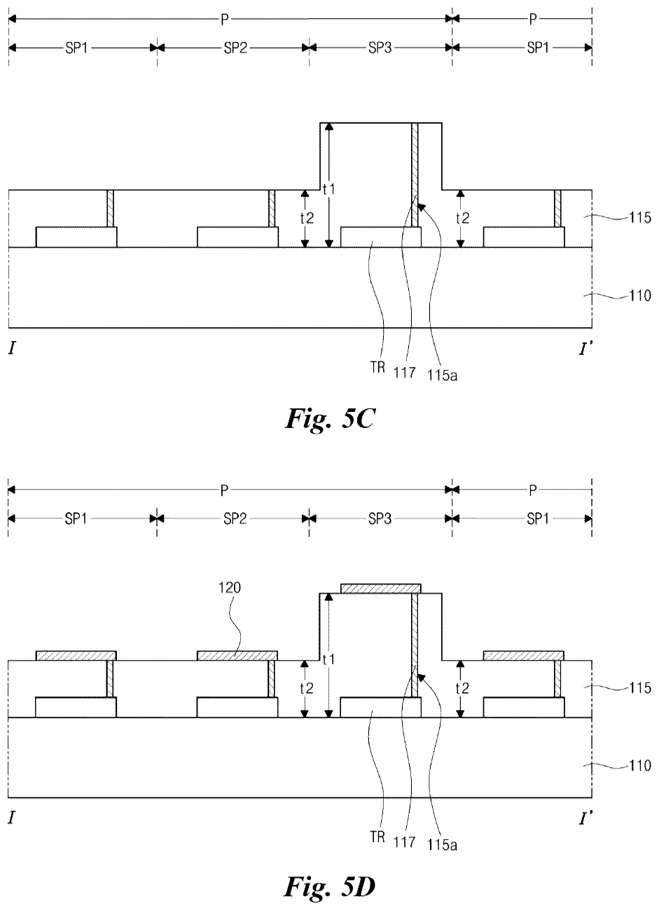

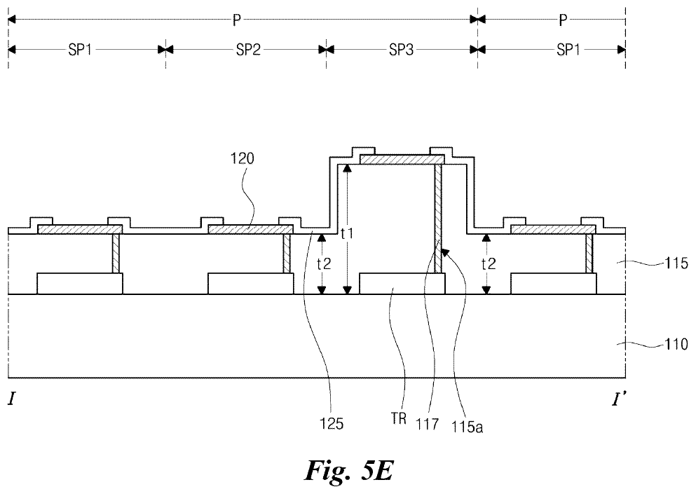

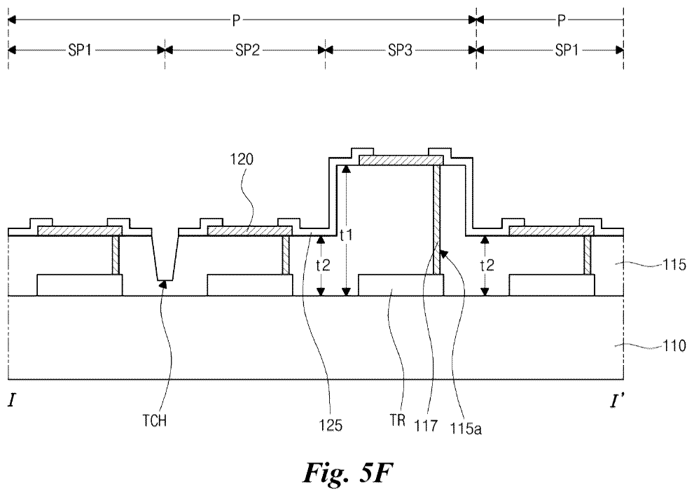

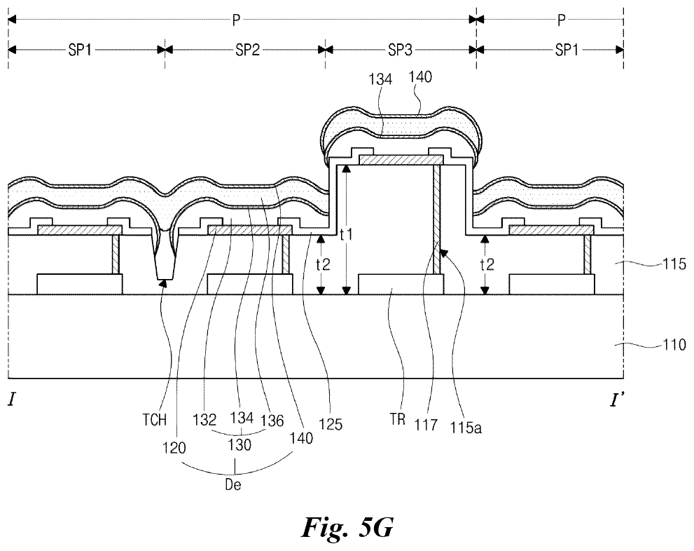

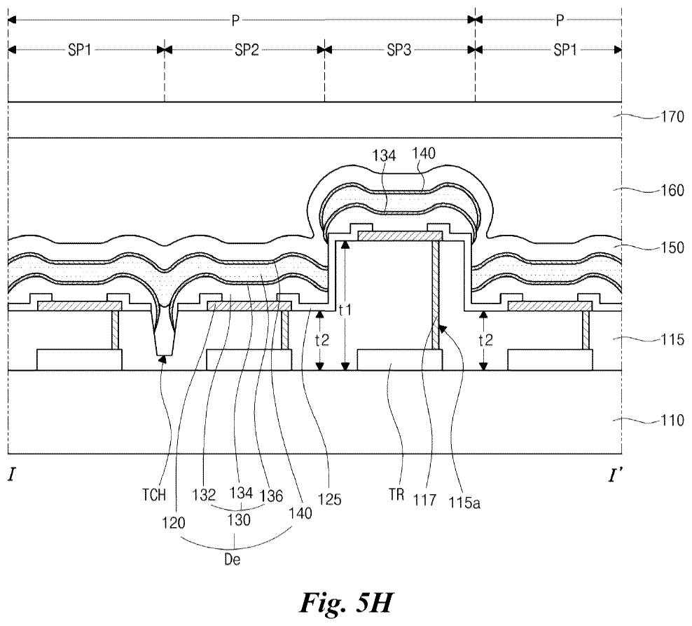

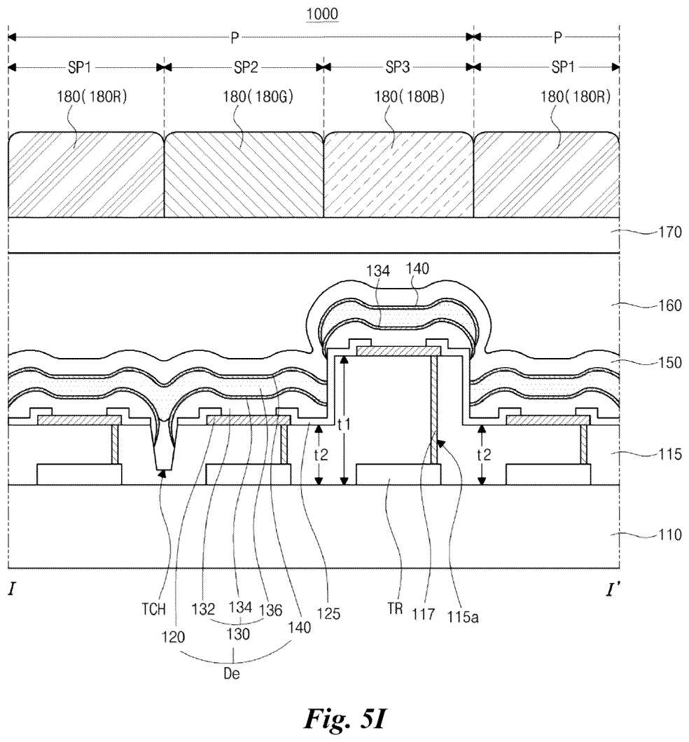

A method of manufacturing the organic light-emitting diode display device 1000 according to the first embodiment of the present disclosure will be described with reference to FIGS. 5A to 5I.

FIGS. 5A to 5I are schematic cross-sectional views of an organic light-emitting diode display device in steps of manufacturing the organic light-emitting diode display device according to the first embodiment of the present disclosure.

In FIG. 5A, the transistor TR can be formed in each of the red, green, and blue sub-pixels SP1, SP2, and SP3 over the substrate 110, a first insulation layer 116 can be formed over the transistor TR over the substantially entire surface of the substrate 110, and a first hole 116a exposing the transistor TR of each sub-pixel SP1, SP2, and SP3 can be formed in the first insulation layer 116 through a photolithography process.

Next, in FIG. 5B, a second insulation layer can be formed over the first insulation layer 116 over the substantially entire surface of the substrate 110, and the second insulation layer corresponding to the red and green sub-pixels SP1 and SP2 and the first hole 116a of FIG. 5A of the blue sub-pixel SP3 can be selectively removed through a photolithography process to thereby form the interlayer insulation layer 115 having the via hole 115a and the different thicknesses and heights.

For example, the interlayer insulation layer 115 of the red and green sub-pixels SP1 and SP2 can include only the first insulation layer 116 of FIG. 5A, and the interlayer insulation layer 115 of the blue sub-pixel SP3 can include the first insulation layer 116 of FIG. 5A and the second insulation layer. Accordingly, the interlayer insulation layer 115 of the blue sub-pixel SP3 can have the first thickness t1, the interlayer insulation layer 115 of the red and green sub-pixels SP1 and SP2 can have the second thickness t2 smaller than the first thickness t1, and the height of the interlayer insulation layer 115 of the blue sub-pixel SP3 can be higher than the height of the interlayer insulation layer 115 of the red and green sub-pixels SP1 and SP2. Here, the first insulation layer 116 of FIG. 5A can have the second thickness t2, and the second insulation layer can have a thickness corresponding to the difference between the first thickness t1 and the second thickness t2.

In addition, the via hole 115a of the red and green sub-pixels SP1 and SP2 can be composed of the first hole 116a of FIG. 5A, and the via hole 115a of the blue sub-pixel SP3 can be composed of the first hole 116a of FIG. 5A and a hole formed in the second insulation layer. Accordingly, the depth of the via hole 115a of the blue sub-pixel SP3 can be deeper than the depth of the via hole 115a of the red and green sub-pixels SP1 and SP2.

Then, in FIG. 5C, the via electrode 117 can be formed by filling the via hole 115 with a metal material. For example, the via electrode 117 can be formed of tungsten, but the embodiments of the present disclosure are not limited thereto.

Next, in FIG. 5D, the first electrode 120 can be formed over the interlayer insulation layer 115 in each of the red, green, and blue sub-pixels SP1, SP2, and SP3. The first electrode 120 can be connected to the transistor TR through the via electrode 117 provided in the via hole 115a of the interlayer insulation layer 115.

Then, in FIG. 5E, the bank 125 can be formed on the first electrode 120. The bank 125 can cover the edges of the first electrode 120 and can have the opening exposing the central portion of the first electrode 120.

Next, in FIG. 5F, the trench TCH can be formed at the boundary between the adjacent red and green sub-pixels SP1 and SP2 by etching the bank 125 and the interlayer insulation layer 115.

In the first embodiment of the present disclosure, it has been described that the trench TCH is formed after forming the bank 125, but the embodiments of the present disclosure are not limited thereto. Alternatively or additionally, the trench TCH can be formed in the interlayer insulation layer 115, and then the first electrode 120 and the bank 125 can be formed.

Next, in FIG. 5G, the first stack 132 and the charge generation layer 134 can be sequentially formed over the first electrode 120 exposed through the opening of the bank 125 and the bank 125. The first stack 132 and the charge generation layer 134 can be formed through a thermal evaporation process. However, the embodiments of the present disclosure are not limited thereto.

The first stack 132 and the charge generation layer 134 can be separated by the trench TCH between the red and green sub-pixels SP1 and SP2. In addition, the first stack 132 and the charge generation layer 134 can be separated by the difference in the thickness and height of the interlayer insulation layer 115 between the red and blue sub-pixels SP1 and SP3 and between the green and blue sub-pixels SP2 and SP3. Accordingly, the first stack 132 and the charge generation layer 134 of the adjacent sub-pixels SP1, SP2, and SP3 may not be connected to each other, and the first stack 132 and the charge generation layer 134 can be separated for each of the sub-pixels SP1, SP2, and SP3.

In this case, between the red and green sub-pixels SP1 and SP2, each of the first stack 132 and the charge generation layer 134 can be formed along a side wall of the trench TCH, and can be thinner on the side wall of the trench TCH as it approaches the substrate 110 and then be cut off. Furthermore, each of the first stack 132 and the charge generation layer 134 can be formed along the bank 125 formed at the side surface of the interlayer insulation layer 115 having the first thickness t1, and can be thinner as it approaches the substrate 110 and then be cut off.

Then, the second stack 136 and the second electrode 140 can be sequentially formed on the charge generation layer 134. The second stack 136 and the second electrode 140 can be formed through a thermal evaporation process. However, the embodiments of the present disclosure are not limited thereto.

Here, the second stack 136 and the second electrode 140 of the red and green sub-pixels SP1 and SP2 adjacent to each other can be connected to each other without being separated. Alternatively or additionally, the second stack 136 and the second electrode 140 of the red and green sub-pixels SP1 and SP2 can be separated.

In some embodiments, the second stack 136 and the second electrode 140 of the blue sub-pixel SP3 can be separated from the second stack 136 and the second electrode 140 of the red and green sub-pixels SP1 and SP2 adjacent thereto, respectively. In this case, the second stack 136 of the blue sub-pixel SP3 can expose opposite edges of the charge generation layer 134, and the second electrode 140 can be in contact with the exposed opposite edges of the charge generation layer 134. Accordingly, in the blue sub-pixel SP3, the second electrode 140 can be electrically connected to the charge generation layer 134, and the second electrode 140 and the charge generation layer 134 can be short-circuited with the relatively high resistance.

Next, in FIG. 5H, the first, second, and third encapsulation layers 150, 160, and 170 can be sequentially formed over the second electrode 140. In this case, the first and third encapsulation layers 150 and 170 can be formed through a deposition process having excellent step coverage. Accordingly, the first and third encapsulation layers 150 and 170 can be formed along the steps of the layers thereunder and can have a non-flat top surface.

On the other hand, the second encapsulation layer 160 can eliminate the step difference caused by the layers thereunder and can have a substantially flat top surface. The second encapsulation layer 160 can be formed through a solution process. However, the embodiments of the present disclosure are not limited thereto. Alternatively or additionally, the second encapsulation layer 160 can be formed through a deposition process.

Next, in FIG. 5I, by repeating steps of applying a color resist over the third encapsulation layer 170 and patterning it through a photolithography process, the red, green, and blue color filters 180R, 180G, and 180B can be formed in the red, green, and blue sub-pixels SP1, SP2, and SP3, respectively, to thereby complete the color filter 180.

As described above, in the organic light-emitting diode display device 1000 according to the first embodiment of the present disclosure, by forming two insulation layers, the interlayer insulation layer 115 can be formed. That is, the interlayer insulation layer 115 can be formed by forming the second insulation layer having the thickness corresponding to the difference between the first thickness t1 and the second thickness t2 in the blue sub-pixel SP3 after forming the first insulation layer 116 of FIG. 5A having the second thickness t2 in the red, green, and blue sub-pixels SP1, SP2, and SP3.

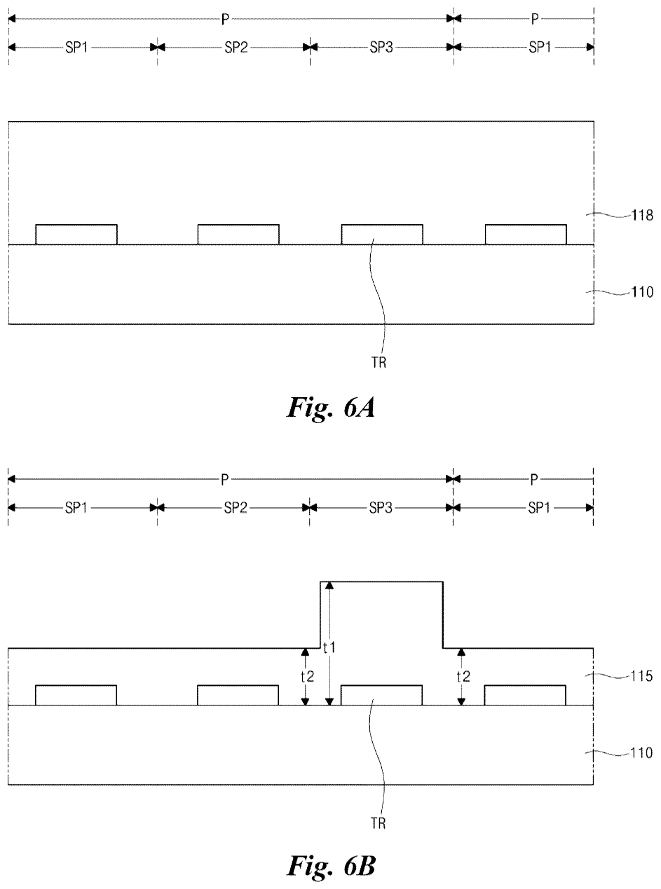

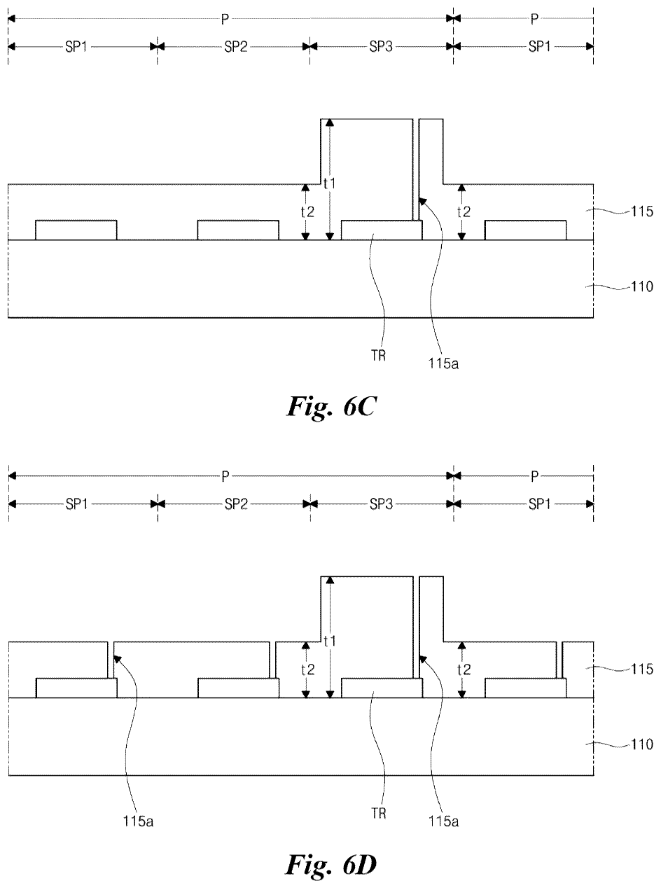

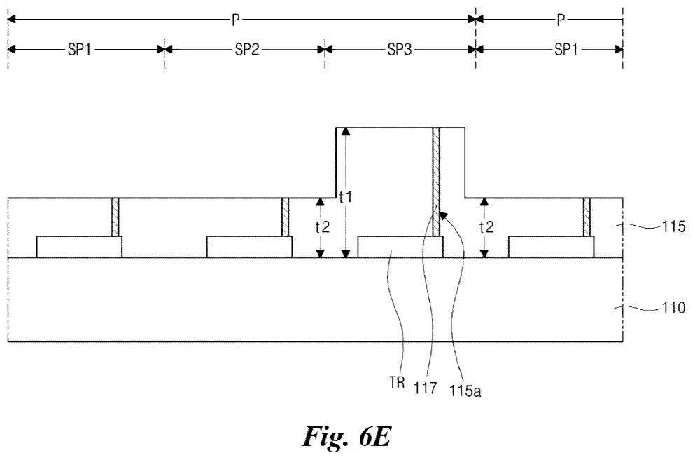

Alternatively or additionally, the interlayer insulation layer 115 of the present disclosure can be formed using one insulation layer. This will be described in detail with reference to FIGS. 6A to 6E.

FIGS. 6A to 6E are schematic cross-sectional views of an organic light-emitting diode display device in steps of manufacturing the organic light-emitting diode display device of another example according to the first embodiment of the present disclosure.

In FIG. 6A, the transistor TR can be formed in each of the red, green, and blue sub-pixels SP1, SP2, and SP3 over the substrate 110, and an insulation layer 118 can be formed over the transistor TR over the substantially entire surface of the substrate 110.

Next, in FIG. 6B, the interlayer insulation layer 115 having different thicknesses and heights can be formed by selectively removing the insulation layer 118 of FIG. 6A of the red and green sub-pixels SP1 and SP2 through a photolithography process. Here, the interlayer insulation layer 115 of the blue sub-pixel SP3 can have the first thickness t1, and the interlayer insulation layer 115 of the red and green sub-pixels SP1 and SP2 can have the second thickness t2 smaller than the first thickness t1.

Then, in FIG. 6C, the via hole 115a can be formed in the interlayer insulation layer 115 of the blue sub-pixel SP3 through a photolithography process.

Next, in FIG. 6D, the via hole 115a can be formed in the interlayer insulation layer 115 of the red and green sub-pixels SP1 and SP2 through another photolithography process.

Alternatively or additionally, after the via hole 115a is formed in the interlayer insulation layer 115 of the red and green sub-pixels SP1 and SP2, the via hole 115a can be formed in the interlayer insulation layer 115 of the blue sub-pixel SP3.

Since the via hole 115a of the blue sub-pixel SP3 and the via hole 115a of the red and green sub-pixels SP1 and SP2 have the different depths, they are desirably formed through different photolithography processes. However, the embodiments of the present disclosure are not limited thereto.

Then, in FIG. 6E, the via electrode 117 can be formed by filling the via hole 115a with a metal material. For example, the via electrode 117 can be formed of tungsten, but the embodiments of the present disclosure are not limited thereto.

Next, the steps of FIGS. 5D to 5I can be performed, thereby completing the organic light-emitting diode display device 1000 according to the first embodiment of the present disclosure.

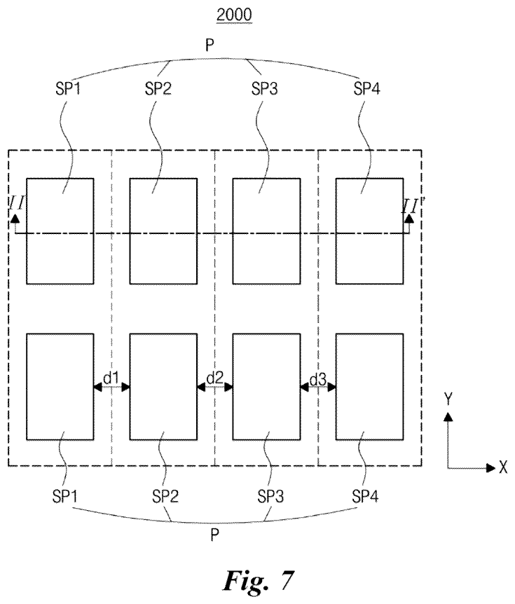

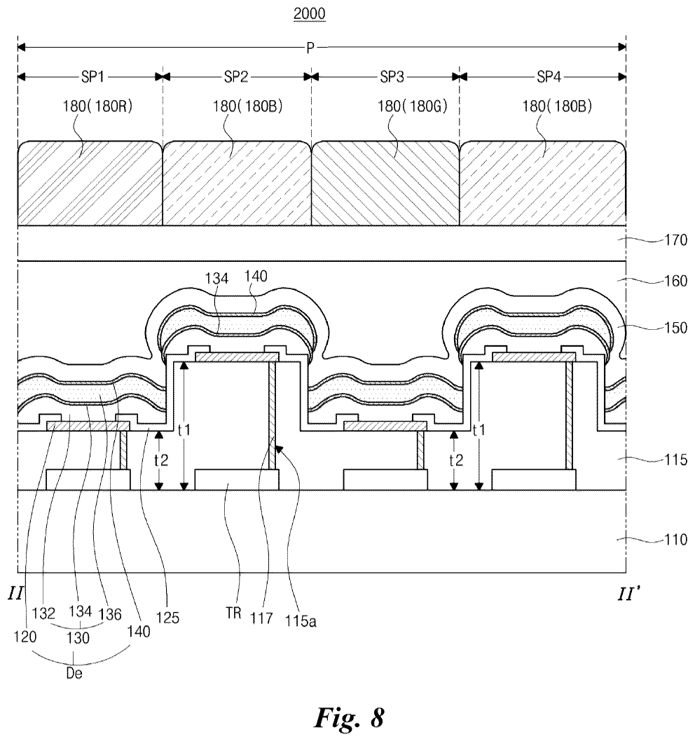

In some embodiments, one pixel P can include three sub-pixels, that is, the red, green, and blue sub-pixels SP1, SP2, and SP3 as an example. However, in other embodiments of the present disclosure, one pixel can include one red sub-pixel, one green sub-pixel, and two blue sub-pixels. Examples of those embodiments of the present disclosure will be described with reference to FIG. 7 and FIG. 8.

FIG. 7 is a plan view schematically illustrating an organic light-emitting diode display device according to a second embodiment of the present disclosure.

In FIG. 7, the organic light-emitting diode display device 2000 according to the second embodiment of the present disclosure can include a plurality of pixels P arranged in a matrix form along a first direction, which is an X direction, and a second direction, which is a Y direction. Each pixel P can include a plurality of sub-pixels SP1, SP2, and SP3. Two pixels P arranged along the second direction may be shown in FIG. 7, but a plurality of pixels P having the same configuration can also be arranged along the first direction.

One pixel P can include one red sub-pixel SP1, one green sub-pixel SP3, and two blue sub-pixels SP2 and SP4. In this case, the red, blue, green, and blue sub-pixels SP1, SP2, SP3, and SP4 can be arranged in order along the first direction. That is, a first blue sub-pixel SP2 or a second blue sub-pixel SP4 can be disposed between the red and green sub-pixels SP1 and SP3. For example, the first blue sub-pixel SP2 can be disposed between the red and green sub-pixels SP1 and SP3 of the pixel P, and the second blue sub-pixel SP4 can be disposed between the green sub-pixel SP3 of the pixel P and a red sub-pixel of another pixel adjacent thereto.

Here, at least one thin film transistor and a light-emitting diode can be provided at each of the sub-pixels SP1, SP2, SP3, and SP4. In FIG. 7, an area corresponding to each sub-pixel SP1, SP2, and SP3 can substantially mean an emission area.

Distances between the emission areas of the adjacent sub-pixels SP1, SP2, SP3, and SP4 can be the same. For example, a first distance d1 between the emission areas of the red and first blue sub-pixels SP1 and SP2, a second distance d2 between the emission areas of the first blue and green sub-pixels SP2 and SP3, and a third distance d3 between the emission areas of the green and second blue sub-pixels SP3 and SP4 can be the same as each other.

A cross-sectional structure of the organic light-emitting diode display device according to the second embodiment of the present disclosure will be described with reference to FIG. 8.

FIG. 8 is a cross-sectional view of an organic light-emitting diode display device according to the second embodiment of the present disclosure and shows a cross-section taken along the line II-II′ of FIG. 7. The organic light-emitting diode display device 2000 according to the second embodiment of the present disclosure can have substantially the same configurations as those of the first embodiment except for the arrangement of the sub-pixels and the trench. The same parts as those of the first embodiment are designated by the same reference signs, and explanation for the same parts will be shortened or omitted.

In FIG. 8, the organic light-emitting diode display device 2000 of the second embodiment of the present disclosure can include red, first blue, green, and second blue sub-pixels SP1, SP2, SP3, and SP4 sequentially provided over a substrate 110. Each of the red, first blue, green, and second blue sub-pixels SP1, SP2, SP3, and SP4 can include a transistor TR and a light-emitting diode De.

Specifically, the transistor TR can be disposed in each of the red, first blue, green, and second blue sub-pixels SP1, SP2, SP3, and SP4 over the substrate 110. An interlayer insulation layer 115 can be provided over the thin film transistor TR.

Thickness and height of the interlayer insulation layer 115 in the first and second blue sub-pixels SP2 and SP4 can be greater than thickness and height of the interlayer insulation layer 115 in the red and green sub-pixels SP1 and SP3.

That is, the interlayer insulation layer 115 in the first and second blue sub-pixels SP2 and SP4 can have a first thickness t1, and the interlayer insulation layer 115 in the red and green sub-pixels SP1 and SP3 can have a second thickness t2. The first thickness t1 can be greater than the second thickness t2. Accordingly, a first height of the interlayer insulation layer 115 in the first and second blue sub-pixels SP2 and SP4 can be higher than a second height of the interlayer insulation layer 115 in the red and green sub-pixels SP1 and SP3.

In this case, a side surface of the interlayer insulation layer 115 in the first and second blue sub-pixels SP2 and SP4 can be substantially perpendicular to the substrate 110 or can be reversely inclined with respect to the substrate 110 such that a width of a portion of the interlayer insulation layer 115 corresponding to the first and second blue sub-pixels SP2 and SP4 may increase upwards, that is, far away from the substrate 110.

The interlayer insulation layer 115 can have a via hole 115a exposing the transistor TR in each sub-pixel SP1, SP2, SP3, and SP4, and a via electrode 117 can be provided in the via hole 115a.

A first electrode 120 can be provided in each of the red, first blue, green, and second blue sub-pixels SP1, SP2, SP3, and SP4 over the interlayer insulation layer 115. The first electrode 120 can be connected to the transistor TR through the via hole 115a provided in the interlayer insulation layer 115.

A bank 125 can be disposed over the first electrode 120. The bank 125 can cover edges of the first electrode 120 and have an opening exposing a central portion of the first electrode 120.

The bank 125 can be formed along a side surface of a portion of the interlayer insulation layer 115 having the first thickness t1.

A light-emitting layer 130 can be disposed over the first electrode 120 exposed through the opening of the bank 125 and the bank 125. The light-emitting layer 130 can include a first stack 132, a charge generation layer 134, and a second stack 136.

Due to the thickness and height of the interlayer insulation layer 115, the light-emitting layer 130 can be separated for each sub-pixel SP1, SP2, SP3, and SP4. In this case, a difference between the first thickness t1 and the second thickness t2 of the interlayer insulation layer 115, desirably, can be greater than a thickness of the light-emitting layer 115. The thickness of the light-emitting layer 130 can be defined as a distance between the first electrode 120 and a second electrode 140. For example, the difference between the first thickness t1 and the second thickness t2 can be 3000 Å or more. However, the embodiments of the disclosure are not limited thereto.

The first stack 132, the charge generation layer 134, and the second stack 136 of each of the first and second blue sub-pixels SP2 and SP4 can be separated from the first stack 132, the charge generation layer 134, and the second stack 136 of each of the red and green sub-pixel SP1 and SP3 adjacent thereto.

Each of the first stack 132, the charge generation layer 134, and the second stack 136 of each of the first and second blue sub-pixels SP2 and SP4 can be formed along the bank 125 formed at the side surface of the portion of the interlayer insulation layer 115 having the first thickness t1, and can be thinner as it approaches the substrate 110 and then be cut off. In this case, the first stack 132 and the charge generation layer 134 can be in contact with the bank 125, and the second stack 136 can be spaced apart from the bank 125 and expose opposite edges of the charge generation layer 134.

Also, the first stack 132, the charge generation layer 134, and the second stack 136 of each of the red and green sub-pixels SP1 and SP3 can be in contact with the bank 125 formed at the side surface of the portion of the interlayer insulation layer 115 having the first thickness t1.

In the organic light-emitting diode display device 2000 according to the second embodiment of the present disclosure, the first stack 132, the charge generation layer 134, and the second stack 136 can be separated and spaced apart for each sub-pixel SP1, SP2, SP3, and SP4 due to the difference in the thickness and height of the interlayer insulation layer 115, thereby minimizing the lateral leakage current between the adjacent sub-pixels SP1, SP2, SP3, and SP4 emitting light of different colors.

The second electrode 140 can be provided over the light-emitting layer 130. Here, the second electrode 140 can be separated for each sub-pixel SP1, SP2, SP3, and SP4. That is, the second electrode 140 of the first and second blue sub-pixels SP2 and SP4 can be separated from the second electrode 140 of the red and green sub-pixels SP1 and SP3 adjacent thereto.

In this case, opposite edges of the second electrode 140 of each of the first and second blue sub-pixels SP2 and SP4 can be thinner as it approaches the substrate 110 and then be cut off, thereby being in contact with the exposed charge generation layer 134 of each of the first and second blue sub-pixels SP2 and SP4. Accordingly, in each of the first and second blue sub-pixels SP2 and SP4, the second electrode 140 can be electrically connected to the charge generation layer 134. That is, in each of the first and second blue sub-pixels SP2 and SP4, the second electrode 140 can be electrically short-circuited to the charge generation layer 134 with relatively high resistance.

On the other hand, the second electrode 140 of each of the red and green sub-pixels SP1 and SP3 can be in contact with the bank 125 formed at the side surface of the portion of the interlayer insulation layer 115 having the first thickness t1.

Here, it has bed described that the second electrode 140 can be separated for each sub-pixel SP1, SP2, SP3, and SP4, but the embodiments of the present disclosure are not limited thereto. Alternatively or additionally, the second electrode 140 can be connected without being separated for each sub-pixel SP1, SP2, SP3, and SP4. That is, the second electrode 140 of the first and second blue sub-pixels SP2 and SP4 can be connected to the second electrode 140 of the red and green sub-pixels SP1 and SP3 adjacent thereto.

First, second, and third encapsulation layers 150, 160, and 170 can be sequentially provided over the second electrode 140. The first and third encapsulation layers 150 and 170 can be formed of an inorganic insulating material, and the second encapsulation layer 160 can be formed of an organic insulating material.

Next, a color filter 180 can be provided over the third encapsulation layer 170. The color filter 180 can include red and green color filters 180R and 180G corresponding to the red and green sub-pixels SP1 and SP3, respectively, and also include a blue color filter 180B corresponding to each of the first and second blue sub-pixels SP2 and SP4.

Although not shown in the figures, a cover substrate or cover film can be provided over the color filter 180.

The organic light-emitting diode display device 2000 according to the second embodiment of the present disclosure can be formed by substantially the same method as that described in FIGS. 5A to 5I or FIGS. 6A to 6E except for the step of forming the trench TCH.

As described above, in the organic light-emitting diode display device 2000 according to the second embodiment of the present disclosure, by varying the thickness and height of the interlayer insulation layer 115 in the adjacent sub-pixels SP1, SP2, SP3, and SP4, the first stack 132, the charge generation layer 134, and the second stack 136 between the adjacent sub-pixels SP1, SP2, SP3, and SP4 of different colors can be separated, thereby minimizing the lateral leakage current.

In this case, since the trench TCH can be omitted between the adjacent sub-pixels SP1, SP2, SP3, and SP4, a photo mask can be omitted, thereby reducing costs for the mask, and manufacturing time and costs can be decreased. Further, the size of the emission area can be increased within the same area, thereby increasing the aperture ratio.

Additionally, in each of the first and second blue sub-pixels SP2 and SP4, the edges of the second electrode 140 can be in contact with the charge generation layer 134, the second electrode 140 and the charge generation layer 134 can be electrically connected to each other, thereby improving the color purity of blue light at the low gray levels.

Moreover, since the intensities of the red light and the green light at the low gray levels are relatively small, the color material of the blue color filter 180B can be reduced or the thickness of the blue color filter 180B can be decreased. Accordingly, the transmittance of the blue color filter 180B can be increased, so that the efficiency of the blue color can be increased.

The organic light-emitting diode display device according to the embodiment of the present disclosure can be applied to a head mounted display. A head mounted display is a virtual reality (VR) or augmented reality (AR) glasses-type monitor device that is worn in the form of glasses or a helmet and focuses on a distance close to the user's eyes. It can be implemented by arranging various optical systems on the front surface of the organic light-emitting diode display device according to the embodiment of the present disclosure.

In the present disclosure, the lateral leakage current between adjacent sub-pixels can be minimized by disposing the trench between the adjacent sub-pixels of different colors or varying the thickness and height of the interlayer insulation layer between the adjacent sub-pixels of different colors. Accordingly, the color reproducibility can be improved.

Due to the thickness and height of the interlayer insulation layer, the trench can be omitted, so that the aperture ratio can be increased, thereby improving the luminance.

In addition, due to the thickness and height of the interlayer insulation layer, the color purity of the blue color at the low gray levels can be improved, and the efficiency of the blue color can be increased.

Further, it is possible to lower the power consumption through the improved luminance, efficiency, and color reproducibility, thereby reducing the power consumption.

It will be apparent to those skilled in the art that various modifications and variations can be made in the display device of the present disclosure without departing from the technical idea or scope of the disclosure. Thus, it is intended that the present disclosure cover the modifications and variations of this disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light-emitting diode display device, comprising:
a substrate including a first sub-pixel and a second sub-pixel;
an interlayer insulation layer over the substrate and having different heights; and
a first light-emitting diode disposed at the first sub-pixel and a second light-emitting diode disposed at the second sub-pixel over the substrate,
wherein each of the first light-emitting diode or second light-emitting diode includes a first electrode, a light-emitting layer, and a second electrode, and the light-emitting layer includes a first stack, a charge generation layer, and a second stack, and
wherein the second electrode of the first light-emitting diode is electrically connected to the charge generation layer of the first light-emitting diode, and the second electrode of the second light-emitting diode is separated from the charge generation layer of the second light-emitting diode.

2. The organic light-emitting diode display device of claim 1, wherein the interlayer insulation layer in the first sub-pixel has a first height, and the interlayer insulation layer in the second sub-pixel has a second height smaller than the first height.

3. The organic light-emitting diode display device of claim 2, wherein a difference between the first height and the second height is greater than a thickness of the light-emitting layer.

4. The organic light-emitting diode display device of claim 2, wherein the charge generation layer of the first light-emitting diode is separated from the charge generation layer of the second light-emitting diode, and the second electrode of the first light-emitting diode is separated from the second electrode of the second light-emitting diode.

5. The organic light-emitting diode display device of claim 4, wherein the first and second stacks of the first light-emitting diode are separated from the first and second stacks of the second light-emitting diode, respectively.

6. The organic light-emitting diode display device of claim 2, wherein the substrate includes a third sub-pixel and a third light-emitting diode disposed at the third sub-pixel over the substrate, and the second sub-pixel is disposed between the first sub-pixel and the third sub-pixel, and
wherein the interlayer insulation layer has a trench between the second sub-pixel and the third sub-pixel.

7. The organic light-emitting diode display device of claim 6, wherein the third light-emitting diode includes a charge generation layer that is separated from the charge generation layer of the second light-emitting diode, and
wherein a second electrode of the third light-emitting diode is connected to the second electrode of the second light-emitting diode.

8. The organic light-emitting diode display device of claim 6, wherein the interlayer insulation layer in the third sub-pixel has the second height.

9. The organic light-emitting diode display device of claim 2, further comprising
a blue color filter disposed over the first light-emitting diode in the first sub-pixel, and a red or a green color filter disposed over the second light-emitting diode in the second sub-pixel.

10. The organic light-emitting diode display device of claim 2, wherein the substrate includes a third sub-pixel and a fourth sub-pixel, and the first, second, third, and fourth sub-pixels are sequentially arranged, and
wherein the interlayer insulation layer in the third sub-pixel has the first height, and the interlayer insulation layer in the fourth sub-pixel has the second height.

11. The organic light-emitting diode display device of claim 10, further comprising,
a blue color filter disposed in each of the first and third sub-pixels, a red color filter disposed in one of the second and fourth sub-pixels, and a green color filter is disposed in another one of the second and fourth sub-pixels.

12. An organic light-emitting diode display device, comprising:
a substrate including a first sub-pixel and a second sub-pixel;
an interlayer insulation layer over the substrate; and
a light-emitting diode disposed at each of the first and second sub-pixels over the substrate,
wherein the light-emitting diode includes a first electrode, a light-emitting layer, and a second electrode, and the light-emitting layer includes a first stack, a charge generation layer, and a second stack, and
wherein a first height of the interlayer insulation layer in the first sub-pixel is higher than a second height of the interlayer insulation layer in the second sub-pixel.

13. The organic light-emitting diode display device of claim 12, wherein a difference between the first height and the second height is greater than a thickness of the light-emitting layer.

14. The organic light-emitting diode display device of claim 12, wherein a charge generation layer of a light-emitting diode disposed at the first sub-pixel is separated from a charge generation layer of a light-emitting diode disposed at the second sub-pixel, and a second electrode of the light-emitting diode disposed at the first sub-pixel is separated from a second electrode of the light-emitting diode disposed at the second sub-pixel.

15. The organic light-emitting diode display device of claim 14, wherein the first and second stacks of the light-emitting diode disposed at the first sub-pixel are separated from the first and second stacks of the light-emitting diode disposed at the second sub-pixel, respectively.

16. The organic light-emitting diode display device of claim 12, wherein the substrate includes a third sub-pixel, and the second sub-pixel is disposed between the first sub-pixel and the third sub-pixel, and
wherein the interlayer insulation layer has a trench between the second sub-pixel and the third sub-pixel.

17. The organic light-emitting diode display device of claim 16, wherein a charge generation layer of a light-emitting diode disposed at the third sub-pixel is separated from a charge generation layer of a light-emitting diode disposed at the second sub-pixel, and
wherein a second electrode of the light-emitting diode disposed at the third sub-pixel is connected to a second electrode of the light-emitting diode disposed at the second sub-pixel.

18. The organic light-emitting diode display device of claim 16, wherein the interlayer insulation layer in the third sub-pixel has the second height.

19. The organic light-emitting diode display device of claim 12, further comprising a blue color filter disposed in the first sub-pixel, and a red or a green color filter disposed in the second sub-pixel.

20. The organic light-emitting diode display device of claim 12, wherein the substrate includes a third sub-pixel and a fourth sub-pixel, and the first, second, third, and fourth sub-pixels are adjacent to one another, and
wherein the interlayer insulation layer in the third sub-pixel has the first height, and the interlayer insulation layer in the fourth sub-pixel has the second height.

21. The organic light-emitting diode display device of claim 20, further comprising
a blue color filter disposed in each of the first and third sub-pixels, a red color filter disposed in one of the second or fourth sub-pixels, and a green color filter disposed in another one of the second or fourth sub-pixels.

22. A method of manufacturing an organic light-emitting diode display device, comprising:
forming an interlayer insulation layer over a substrate including a first sub-pixel and a second sub-pixel, the interlayer insulation layer having different heights between a first portion of the interlayer insulation layer on the first sub-pixel and a second portion of the interlayer insulation layer on the second sub-pixel;
forming a first electrode at each of the first and second sub-pixels over the interlayer insulation layer;
forming a light-emitting layer including a first stack, a charge generation layer, and a second stack over each first electrode; and
forming a second electrode over each light-emitting layer,
wherein the second electrode in the first sub-pixel is electrically short-circuited to the charge generation layer in the first sub-pixel, and the second electrode in the second sub-pixel is separated from the charge generation layer in the second sub-pixel.

23. The method of claim 22, wherein the interlayer insulation layer has a first height in the first sub-pixel and a second height in the second sub-pixel and smaller than the first height.

24. The method of claim 23, wherein forming the interlayer insulation layer comprises:
forming a first insulation layer in the first and second sub-pixels, the first insulation layer having the second height; and
forming a second insulation layer in the first sub-pixel, the second insulation layer having a thickness that is substantially equal to a difference between the first height and the second height.

25. The method of claim 23, wherein forming the interlayer insulation layer comprises:
forming an insulation layer in the first and second sub-pixels, the insulation layer having the first height; and
selectively removing the insulation layer in the second sub-pixel to reduce a thickness of the insulation layer by an amount that is substantially equal to a difference between the first height and the second height.

26. An organic light-emitting diode display device, comprising:
a substrate including a first sub-pixel and a second sub-pixel;
an interlayer insulation layer over the substrate and having a first height at the first sub-pixel and a second height at the second sub-pixel; and
a first light-emitting diode disposed at the first sub-pixel and a second light-emitting diode disposed at the second sub-pixel over the substrate, each of the first light-emitting diode or second light-emitting diode including a first electrode, a light-emitting layer, and a second electrode;
wherein a difference between the first height and the second height is greater than a thickness of the light-emitting layer.

27. The organic light-emitting diode display device of claim 1, wherein the interlayer insulation layer includes a first layer on the first sub-pixel and the second sub-pixel and a second layer on the first sub-pixel and not on the second sub-pixel.
